(19) United States
(12) Patent Application Publication
(10) Pub. No.: US 2023/0007765 A1
(43) Pub. Date: Jan. 5, 2023

(54) CIRCUIT STRUCTURE

(71) Applicant: MICROELECTRONICS TECHNOLOGY, INC., Hsinchu (TW)

(72) Inventors: TUNG-HUA YANG, HSINCHU (TW); LE-WEI WANG, HSINCHU (TW); SHIH-HUAN CHIEN, HSINCHU (TW)

(21) Appl. No.: 17/365,276

(22) Filed: Jul. 1, 2021

(51) Int. Cl. H05K 1/02; H01Q 3/34

(52) U.S. Cl. CPC H05K 1/024; H01Q 3/34; H05K 1/0366

(57) ABSTRACT

The present disclosure provides circuit structure configured to decrease a phase difference between a first signal and a second signal. The circuit structure includes substrate. The substrate includes a first conductive layer, a first woven dielectric layer, and a second woven dielectric layer. The first conductive layer is disposed over the substrate. The first conductive layer includes a circuit pattern configured to transmit the first signal and the second signal. The first woven dielectric layer is stacked below the first conductive layer. The first woven dielectric layer has a plurality of first opens. The second woven dielectric layer is stacked below the first woven dielectric layer. The second woven dielectric layer has a plurality of second opens. The plurality of first opens and the plurality of second opens are misaligned from a top view.

### TECHNICAL FIELD

The present disclosure relates to a circuit structure, and more particularly, to a circuit structure having a plurality of woven dielectric layers.

### DISCUSSION OF THE BACKGROUND

In power splitter circuit, each split signal has the identical properties to each other. However, when each split signals are transmitted to other place through different paths, the properties of signals might change by different scale. Therefore, the properties of the signals are not identical to each. For example, two split signals are in phase before transmission, and the said signals are out of phase after transmission because the path which the signals are experienced are different. If an application needs the pair of signals in phase, the circuit has to adjust the phase difference between the signals before the signals are received or processed by a device which is configured to perform the application.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a circuit structure configured to decrease a phase difference between a first signal and a second signal. The circuit structure includes substrate. The substrate includes a first conductive layer, a first woven dielectric layer, and a second woven dielectric layer. The first conductive layer is disposed over the substrate. The first conductive layer includes a circuit pattern configured to transmit the first signal and the second signal. The first woven dielectric layer is stacked below the first conductive layer. The first woven dielectric layer has a plurality of first opens. The second woven dielectric layer is stacked below the first woven dielectric layer. The second woven dielectric layer has a plurality of second opens. The plurality of first opens and the plurality of second opens are misaligned from a top view.

In some embodiments, the first woven dielectric layer includes a plurality of first fiberglass strips and a plurality of second fiberglass strips. The plurality of first fiberglass strips is disposed along a first direction. The plurality of second fiberglass strips is disposed along a second direction perpendicular to the first direction. The plurality of first fiberglass strips and the plurality of second fiberglass strips are woven together, and the plurality of first opens are formed between two adjacent first fiberglass strips and two adjacent second fiberglass strips.

In some embodiments, the second woven dielectric layer includes a plurality of third fiberglass strips and a plurality of fourth fiberglass strips. The plurality of third fiberglass strips is disposed along a third direction. The plurality of fourth fiberglass strips is disposed along a fourth direction perpendicular to the fourth direction. The plurality of third fiberglass strips and the plurality of fourth fiberglass strips are woven together, and the plurality of second opens are formed between two adjacent third fiberglass strips and two adjacent fourth fiberglass strips.

In some embodiments, an included angle of the first direction and the third direction is ranged from 0 to 90 degree.

In some embodiments, an included angle of the first direction and the third direction is about 45 degree.

In some embodiments, the substrate further includes a second conductive layer stacked below the second woven dielectric layer. The substrate is a printed circuit board.

In some embodiments, the circuit pattern is further configured to receive a source signal and split the source signal into the first signal and the second signal. The circuit pattern includes an input terminal, a first output terminal, and a second output terminal. The input terminal is configured to receive the source signal. The first output terminal is configured to output the first signal. The second output terminal is configured to output the second signal. The circuit pattern is a power splitter circuit.

In some embodiments, the circuit structure further includes a chip, a phase shifter array, and an antenna array. The chip is disposed on the first conductive layer and coupled to the first output terminal and the second output terminal of the circuit pattern, and configured to respectively receive the first signal and the second signal to generate a third signal and a fourth signal. The phase shifter array is coupled to the chip, configured to adjust a phase of the third signal and a phase of the fourth signal to generate a fifth signal and a sixth signal, respectively. The antenna array is coupled to the phase shifter array, and configured to transmit the fifth signal and the sixth signal according to a phase of fifth signal and a phase of the sixth signal, respectively.

In some embodiments, the circuit pattern includes a first conductive trace and second conductive trace. The first conductive trace is configured to transmit the first signal from a first node of the circuit pattern to a second node of the circuit pattern. The second conductive trace is configured to transmit the second signal from a third node of the circuit pattern to a fourth node of the circuit pattern. A phase difference between the first signal at the second node and the first signal at the first node is substantially equal to a phase difference between the second signal at the fourth node and the second signal at the third node.

In some embodiments, the first signal and the second signal are a differential pair.

Another aspect of the present disclosure provides a circuit structure configured to decrease a phase difference between a first signal and a second signal. The circuit structure includes a substrate. The substrate includes a power splitter, a first fiberglass layer, and a second fiberglass layer. The power splitter is disposed on a top conductive layer of the substrate, and the power splitter is configured to split a source signal into the first signal and the second signal. The first fiberglass layer is formed in a first configuration, and the first fiberglass layer is disposed below the top conductive layer. The second fiberglass layer is formed in a second configuration, and the second fiberglass layer is disposed below the first woven fiberglass layer. The first configuration is different from the second configuration.

In some embodiments, the circuit structure includes a chip. The chip is coupled to the power splitter, and configured to receive the first signal and the second signal to generate a third signal and a fourth signal, respectively.

In some embodiments, the circuit structure further includes a phase shifter array and an antenna array. The phase shifter array is configured to perform a phase shifting on the third signal and the fourth signal to generate a fifth signal and a sixth signal, respectively. The antenna array is configured to transmit the fifth signal and the sixth signal according to a phase of fifth signal and a phase of the sixth signal, respectively.

In some embodiments, the first fiberglass layer includes a plurality of first fiberglass strips and a plurality of second fiberglass strips. The plurality of first fiberglass strips is disposed along a first direction. The plurality of second fiberglass strips is disposed along a second direction perpendicular to the first direction. The plurality of first fiberglass strips and the plurality of second fiberglass strips are woven together, and a plurality of first opens are formed between two adjacent first fiberglass strips and two adjacent second fiberglass strips.

In some embodiments, the second fiberglass layer includes a plurality of third fiberglass strips and a plurality of fourth fiberglass strips. The plurality of third fiberglass strips is disposed along a third direction. The plurality of fourth fiberglass strips is disposed along a fourth direction perpendicular to the fourth direction. The plurality of third fiberglass strips and the plurality of fourth fiberglass strips are woven together, and a plurality of second opens are formed between two adjacent third fiberglass strips and two adjacent fourth fiberglass strips.

In some embodiments, an included angle of the first direction and the third direction is greater than 0 degree and less than 90 degree.

In some embodiments, the substrate further includes a bottom conductive layer. The bottom conductive layer and the top conductive layer sandwich the first fiberglass layer and the second fiberglass layer.

In some embodiments, the first signal, the second signal, and the source signal are radio frequency signal.

In some embodiments, the power splitter includes an input terminal, a splitting node, a source conductive trace, a first output terminal, a second output terminal, a first conductive trace, and a second conductive trace. The input terminal is configured to receive the source signal. The source signal is spitted to the first signal and the second signal at the splitting node. The first output terminal is configured to output the first signal. The second output terminal is configured to output the second signal. The source conductive trace couples the input terminal to the splitting node. The first conductive trace couples the splitting node to the first output terminal, configured to transmit the first signal. The second conductive trace couples the splitting node to the second output terminal, configured to transmit the second signal.

In some embodiments, a phase difference between the first signal at the splitting node and the first signal at the first output terminal is substantially equal to a phase difference between the second signal at the splitting node and the second signal at the second output terminal.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic diagram of a schematic diagram of a circuit structure according to some embodiments of the present disclosure.

FIG. 2 is a schematic diagram of the circuit pattern according to some embodiments of the present disclosure.

FIG. 3 is a schematic diagram of a substrate according to some embodiments of the present disclosure.

FIG. 4A is a schematic diagram of a first woven dielectric layer from a top view of the substrate according to some embodiments of the present disclosure.

FIG. 4B is a schematic diagram of a second woven dielectric layer from a top view of the substrate according to some embodiments of the present disclosure.

FIG. 4C is a schematic diagram of a dielectric layer from a top view of the substrate according to some embodiments of the present disclosure.

FIG. 5A is a schematic diagram of a first woven dielectric layer from a top view of the substrate according to alternative embodiments of the present disclosure.

FIG. 5B is a schematic diagram of a second woven dielectric layer from a top view of the substrate according to alternative embodiments of the present disclosure.

FIG. 5C is a schematic diagram of a dielectric layer from a top view of the substrate according to alternative embodiments of the present disclosure.

FIG. 6 is a schematic diagram of a circuit pattern and a dielectric layer from a top view according to some embodiments of the present disclosure.

FIG. 7 is a schematic diagram of a circuit structure in other embodiments of the present disclosure.

FIG. 8 is a schematic diagram of a circuit pattern according to various embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

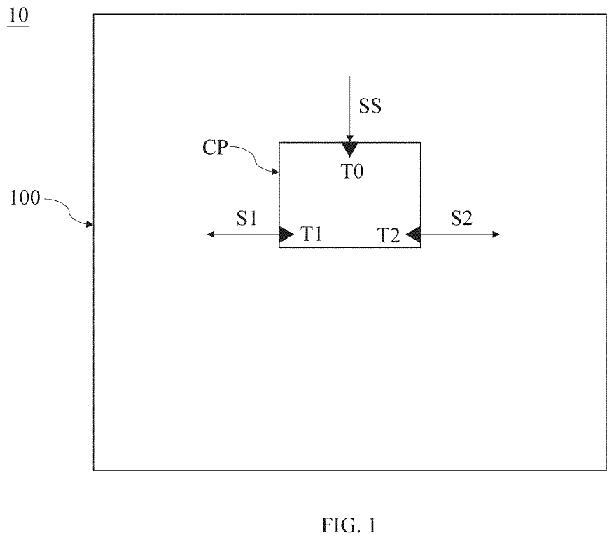

FIG. 1 is a schematic diagram of a circuit structure 10 according to some embodiments of the present disclosure. The circuit structure 10 is configured to transmit a first signal S1 and a second signal S2, and to decrease a phase difference between the first signal S1 and the second signal S2. More specifically, the circuit structure 10 receives a source signal SS to generate the first signal S1 and the second signal S2, and the phase difference between the generated first signal S1 and the generated second signal S2 is substantially equal to zero. In some embodiments, the source SS, the first signal S1, and the second signal S2 are radio frequency signals.

The circuit structure 10 includes a substrate 100. The substrate 100 has a circuit pattern CP thereon. As illustrated in FIG. 1, the circuit pattern CP includes an input terminal T0 configured to receive the source signal SS, a first output terminal T1 configured to output the first signal S1, and a second output terminal T2 configured to output the second signal S2.

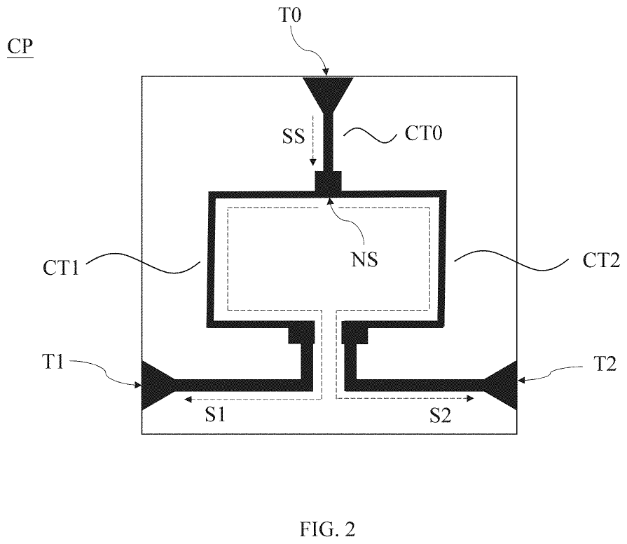

In some embodiments, the circuit pattern CP is a power splitter. Please refer to FIG. 2. FIG. 2 is a schematic diagram of the circuit pattern CP according to some embodiments of the present disclosure.

As illustrated in FIG. 2, the circuit pattern CP further includes a splitting node NS, a conductive trace CT0, a conductive trace CT1, and a conductive trace CT2. The conductive trace CT0 couples the input terminal T0 to the splitting node NS. The conductive trace CT1 couples the splitting node NS to the first output terminal T1. The conductive trace CT2 couples the splitting node NS to the second output terminal T2.

The circuit pattern CP receives the source signal SS by the input terminal T0, and transmit the source signal SS from the input terminal T0 to the splitting node NS through the conductive trace CT0. The source signal SS is split into the first signal S1 and the second S2 at the splitting node NS. The first signal S1 is further transmitted from the splitting node NS to the first output terminal T1 through the conductive trace CT1. The second signal S2 is further transmitted from the splitting node NS to the second output terminal T2 through the conductive trace CT2.

In some embodiments, a power ratio of the first signal S1 to the second signal S2 is substantially equal to 1. In other words, the power of the source signal SS is divided equally at the splitting node NS into the first signal S1 and the second signal S2.

In some embodiments, the conductive trace CT1 and the conductive trace CT2 are symmetrically arranged. Therefore, when the frequency of the first signal S1 is equal to the frequency of the second signal S2, a phase difference Δϕ1 of the first signal S1 between the first output terminal T1 and the splitting node NS is substantially equal to a phase difference Δϕ2 of the second signal S2 between the second output terminal T2 and the splitting node NS. More specifically, the first signal S1 and the second signal S2 have a phase ϕ0 at the splitting node NS, and the first signal S1 and the second signal S2 have a phase ϕ1 and a phase ϕ2 at the first output terminal T1 and the second output terminal T2, respectively. The phase difference Δϕ1 of the first signal S1 is equal to (ϕ1−ϕ0), and the phase difference Δϕ2 of the second signal S2 is equal to (ϕ2−ϕ0).

In some embodiments, the phase difference Δϕ1 and the phase difference Δϕ2 are further associated with dielectric constant of the substrate 100. When the dielectric constant of the substrate 100 varies, the phase difference Δϕ1 might not be equal to the phase difference Δϕ2.

In some approaches, the dielectric constant of the substrate 100 varies with respect to the position, and the first signal S1 traveling through the conductive trace CT1 experiences an effective dielectric constant different from an effective dielectric constant experienced by the second signal S2 which travels through the conductive trace CT2. Therefore, the phase difference Δϕ1 is different from the phase difference Δϕ2.

Compared to the above approaches, the circuit structure 10 of the present disclosure provides the substrate 100 which has a substantially consistent dielectric constant among its entirety. Alternatively stated, the dielectric constant of the substrate 100 substantially does not vary with the position. Therefore, the circuit structure 10 of the present disclosure decreases a difference between the phase difference Δϕ1 and the phase difference Δϕ2. In some embodiments, the circuit structure 10 maintains the phase difference Δϕ1 equal to the phase difference Δϕ2. Please see the description below for details.

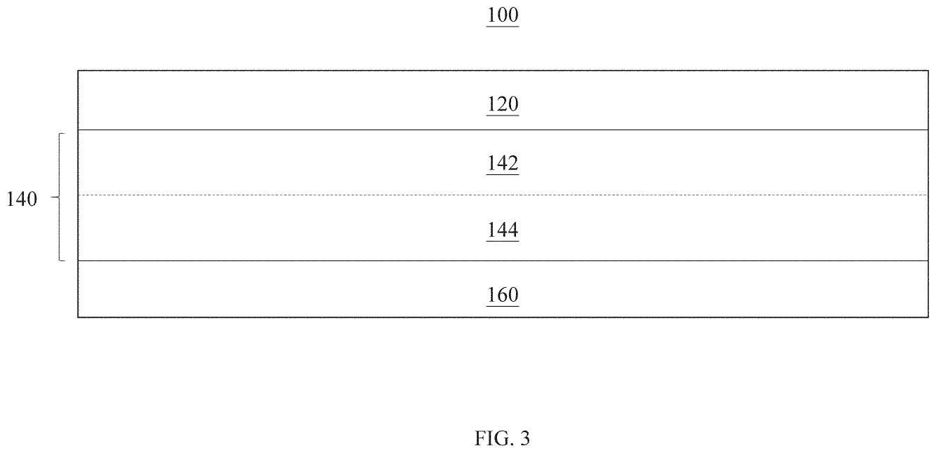

Reference is made to FIG. 3. FIG. 3 is a schematic diagram of the substrate 100 according to some embodiments of the present disclosure. The substrate 100 is a multilayer structure which includes a top conductive layer 120, a dielectric layer 140, and a bottom conductive layer 160. In some embodiments, the substrate 100 is a printed circuit board. The top conductive layer 120 and the bottom conductive layer 160 includes cupper. In some embodiments, the circuit pattern CP is formed by the top conductive layer 120. In some embodiments, the bottom conductive layer 160 is coupled to the ground.

In some embodiments, the dielectric layer 140 includes a first woven dielectric layer 142 and a second woven dielectric layer 144 stacked below the first woven dielectric layer 142, and the first woven dielectric layer 142 and the second woven dielectric layer 144 are bonded together with epoxy resin.

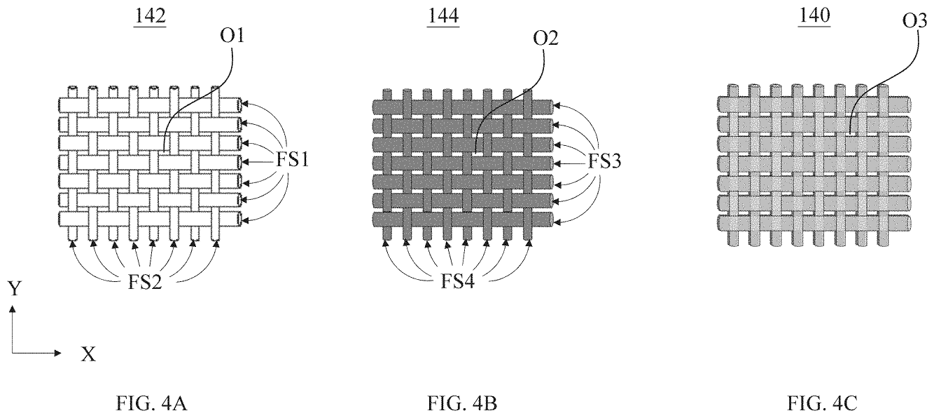

Reference is made to FIG. 4A, FIG. 4B, and FIG. 4C. FIG. 4A, FIG. 4B, and FIG. 4C are schematic diagrams of the first woven dielectric layer 142, the second woven dielectric layer 144, and the dielectric layer 140 from a top view of the substrate 100 according to some embodiments of the present disclosure, respectively. In some embodiments, the first woven dielectric layer 142 and the second woven dielectric layer 144 are woven by fiberglass strips.

As illustrated in FIG. 4A, the first woven dielectric layer 142 includes a plurality of first fiberglass strips FS1 disposed along an X-direction and a plurality of second fiberglass strips FS2 disposed along a Y-direction, in which the second fiberglass strips FS2 are woven with the first fiberglass strips FS1. The X-direction is perpendicular to the Y-direction.

In FIG. 4A, a plurality of first opens O1 are formed between the two adjacent first fiberglass strips FS1 and the two adjacent second fiberglass strips FS2. In some embodiments, the first opens O1 are rectangular.

As illustrated in FIG. 4B, the second woven dielectric layer 144 includes a plurality of third fiberglass strips FS3 disposed along the X-direction and a plurality of fourth fiberglass strips FS4 disposed along the Y-direction, in which the fourth fiberglass strips FS4 are woven with the third fiberglass strips FS3.

In FIG. 4B, a plurality of second opens O2 are formed between the two adjacent third fiberglass strips FS3 and the two adjacent fourth fiberglass strips FS4. In some embodiments, the second opens O2 are rectangular. In some embodiments, each open O2 has a same shape and same size as each open O1.

As illustrated in FIG. 4C, the first woven dielectric layer 142 and the second woven dielectric layer 144 are stacked together, and the first opens O1 and the second opens O2 are misaligned. More particularly, the first opens O1 and the second O2 are not exactly overlapped. At least part of each second open O2 is covered by the first fiberglass strips FS1 and/or the second fiberglass strips FS2, and each first open O1 covers at least part of the third fiberglass strips FS3 and/or that least part of the fourth fiberglass strips FS4.

The dielectric layer 140 has a plurality of opens O3. The opens O3 are regions which are not covered by the first fiberglass strips FS1, the second fiberglass strips FS2, the third fiberglass strips FS3, and the fourth fiberglass strips FS4 from the top view. Because the first opens O1 and the second open O2 are misaligned, each open O3 is respectively smaller than the first opens O1 and the second opens O2 when viewing the first woven dielectric layer 142 and the second woven dielectric layer 144 together from the top view. In other embodiments, the opens O3 do not exist from the top view. In other words, the entire second opens O2 are covered by the first fiberglass strips FS1 and the second fiberglass strips FS2, and the first opens O1 do not cover any part of the second opens O2 from the top view.

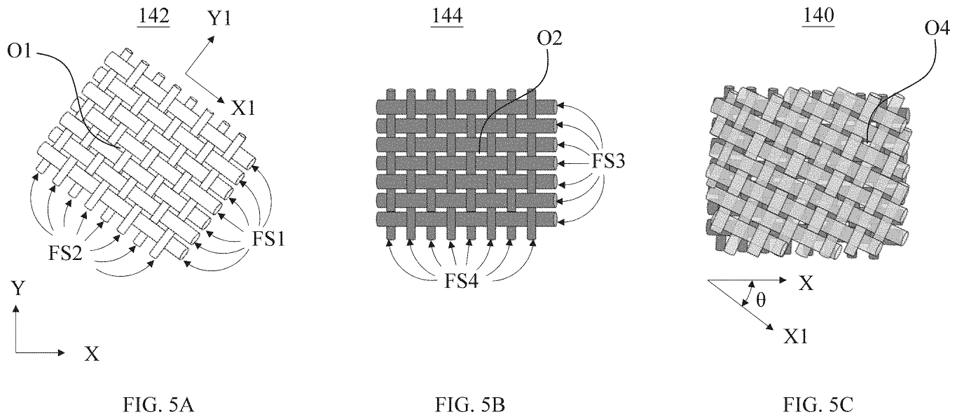

In alternative embodiments, the first woven dielectric layer 142 and the second woven dielectric layer 144 are formed in different configurations. Specifically, the first fiberglass strips FS1 of the first woven dielectric layer 142 and the third fiberglass strips FS3 are not parallel disposed from the top view. Please refer to FIG. 5A, FIG. 5B, and FIG. 5C for details.

Reference is made to FIG. 5A, FIG. 5B, and FIG. 5C. FIG. 5A FIG. 5B, and FIG. 5C are schematic diagrams of the first woven dielectric layer 142, the second woven dielectric layer 144, and the dielectric layer 140 from a top view of the substrate 100 according to alternative embodiments of the present disclosure, respectively.

As illustrated in FIG. 5A, the plurality of first fiberglass strips FS1 are disposed along an X1-direction and the plurality of second fiberglass strips FS2 are disposed along a Y1-direction. The X1-direction is perpendicular to the Y1-direction. The plurality of first opens O1 are formed between the two adjacent first fiberglass strips FS1 and the two adjacent second fiberglass strips FS2.

As illustrated in FIG. 5B, the plurality of third fiberglass strips FS3 are disposed along the X-direction and the plurality of fourth fiberglass strips FS4 are disposed along the Y-direction. The plurality of second opens O2 are formed between the two adjacent third fiberglass strips FS3 and the two adjacent fourth fiberglass strips FS4.

The X1-direction is not parallel to the X-direction. Consequently, the Y1-direction is not parallel to the Y-direction. Alternatively stated, there is an included angle θ of the X1-direction and the X-direction as illustrated in FIG. 5A, and the included angle θ is greater than 0 degree and less than 90 degree. In some embodiments, the included angle θ is about 45 degree.

As illustrated in FIG. 5C, because the X1-direction is different form the X-direction, the first opens O1 and the second opens O2 are thus misaligned. At least part of each second open O2 is covered by the first fiberglass strips FS1 and/or the second fiberglass strips FS2, and each first open O1 covers at least part of the third fiberglass strips FS3 and/or that least part of the fourth fiberglass strips FS4.

The dielectric layer 140 has a plurality of opens O4. The opens O4 are regions which are not covered by the first fiberglass strips FS1, the second fiberglass strips FS2, the third fiberglass strips FS3, and the fourth fiberglass strips FS4 from the top view. Because the first opens O1 and the second open O2 are misaligned, each open O4 is respectively smaller than the first opens O1 and the second opens O2 when viewing the first woven dielectric layer 142 and the second woven dielectric layer 144 together from the top view. In other embodiments, the opens O4 do not exist from the top view. In other words, the entire second opens O2 are covered by the first fiberglass strips FS1 and the second fiberglass strips FS2, and the first opens O1 do not cover any part of the second opens O2 from the top view.

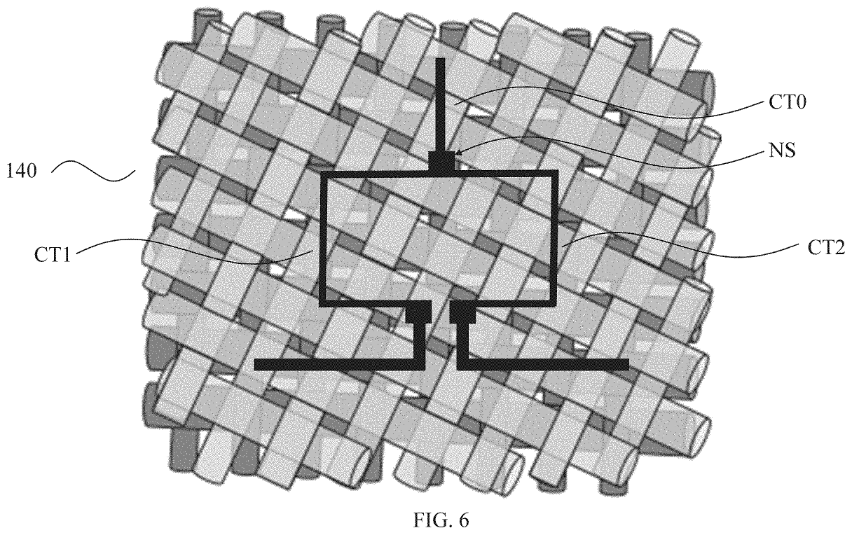

Reference is made to FIG. 6. FIG. 6 is a schematic diagram of the circuit pattern CP and the dielectric layer 140 from the top view according to some embodiments of the present disclosure. In some embodiments, the dielectric layer 140 in FIG. 6 has the same configuration as the dielectric layer 140 shown in FIG. 5C.

In some embodiments, the dielectric constant of the fiberglass strips FS1˜FS4 is different from the dielectric constant of the opens O4. In some embodiments, the fiberglass is a dielectric material, and the opens O4 are filled by epoxy resin or air. The dielectric constant of the fiberglass is greater than the epoxy resin. Therefore, when a region of the dielectric layer 140 includes the fiberglass and epoxy resin, the effective dielectric constant is not consistent among said region.

As illustrated in FIG. 6, in some embodiments, a projected region of the conductive trace CT1 on the dielectric layer 140 does not cross any opens O4, and a projected region of the conductive CT2 on the dielectric layer 140 does not cross any opens O4. Based on the above, the effective dielectric constant is substantially consistent among the projected region of the conductive trace CT1. When the first signal S1 is transmitted through the conductive trace CT1, the first signal S1 experiences a substantially consistent dielectric constant during the transmission. Similarly, the effective dielectric constant is substantially consistent among the projected region of the conductive trace CT2. When the second signal S2 is transmitted through the conductive trace CT2, the second signal S2 experiences a substantially consistent dielectric constant during the transmission.

In some embodiments, the effective dielectric constant which is experienced by the first signal S1 is substantially equal to the effective dielectric constant which is experienced by the second signal S2. In this embodiment, a propagation delay of the first signal S1 is substantially equal to a propagation delay of the second signal S2. Thus, the phase difference Δθ1 of the first signal is substantially equal to the phase difference Δθ2 of the second signal S2. More particularly, the source signal SS is split at the splitting node NS into the first signal S1 and the second S2, and the first signal S1 and the second S2 are in phase at the splitting node NS. Because the phase difference Δθ1 is substantially equal to the phase difference Δθ2, the first signal S1 at the first output terminal T1 and the second signal S2 at the second output terminal T2 are substantially in phase.

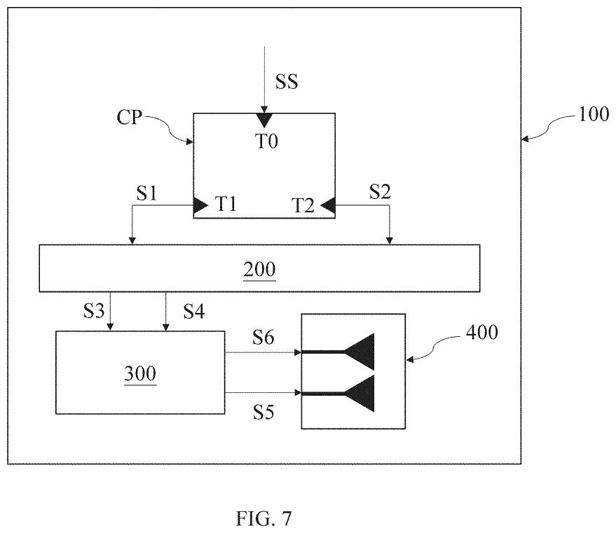

Reference is made to FIG. 7. FIG. 7 is a schematic diagram of the circuit structure 10 in other embodiments of the present disclosure. The circuit structure 10 further includes a chip 200, a phase shifter array 300, and an antenna array 400. The chip 200 is disposed on the top conductive layer of the substrate 100, and coupled to the circuit pattern CP. The phase shifter array 300 is coupled to the chip 200. The antenna array 400 is coupled to the phase shifter array 300.

The chip 200 is coupled to the first output terminal T1 and the second output terminal T2, and configured to receive the first signal S1 and the second signal S2. The chip 200 is further configured to process the first signal S1 and the second signal S2 to generate a third signal S3 and a fourth signal S4, respectively.

The phase shifter array 300 is configured receive the third signal S3 and the fourth signal S4, and to shift a phase of the third signal S3 and a phase of the fourth signal S4 to generate a fifth signal S5 and a sixth signal S6, respectively. In some embodiments, when the chip 200 processes the first signal S1 and the second signal S2, the chip 200 also introduce a phase difference therebetween. Therefore, the third signal S3 and the fourth signal S4 have a phase difference therebetween. The phase shifter array 300 is configured to adjust the phase difference between the third signal S3 and the fourth signal S4, so as to make the fifth signal S5 and the sixth signal in phase.

The antenna array is configured to receive the fifth signal S5 and the sixth signal S6, and transmit the fifth signal S5 and the sixth signal S6 according to a phase of the fifth signal S5 and a phase of the sixth signal S6, respectively. The phase of the fifth signal S5 and the phase of the sixth signal S6 are associated with a transmitted direction.

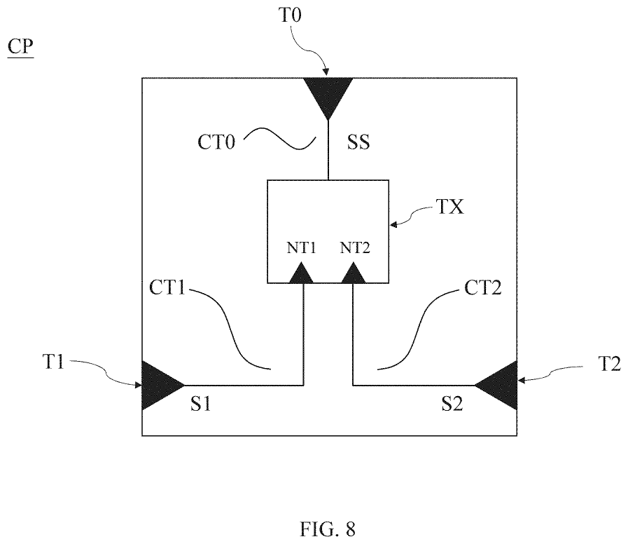

The arrangement of the circuit structure 10 above is provided for illustrative purposes. The present disclosure is not limited thereto. Various arrangements of the circuit structure 10 are within the contemplated scope of the present disclosure. For example, in various embodiments, the circuit pattern CP has different structure as shown in FIG. 8.

Reference is made to FIG. 8. FIG. 8 is a schematic diagram of the circuit pattern CP according to various embodiments of the present disclosure. Compared to the circuit pattern CP shown in FIG. 2, the circuit pattern CP further includes a transmitter TX in various embodiments.

The transmitter TX is configured to receive the source signal SS to generate a differential signal pair, i.e., the first signal S1 and the second signal S2. The first signal S1 is transmitted from a first transmitting node NT1 to the first output terminal T1, and the second signal S2 is transmitted from a second transmitting node NT2 to the second output terminal T2.

Similar to the circuit pattern CP shown in FIG. 1 to FIG. 7, the phase difference Δθ1 of the first signal S1 between first terminal T1 and the first transmitting node NT1 is substantially equal to the phase difference Δθ2 of the second signal S2 between the second output terminal T2 and the second transmitting node NT2. Therefore, the first signal S1 and the second signal S2 are substantially in phase.

One aspect of the present disclosure provides a circuit structure configured to decrease a phase difference between a first signal and a second signal. The circuit structure includes substrate. The substrate includes a first conductive layer, a first woven dielectric layer, and a second woven dielectric layer. The first conductive layer is disposed over the substrate. The first conductive layer includes a circuit pattern configured to transmit the first signal and the second signal. The first woven dielectric layer is stacked below the first conductive layer. The first woven dielectric layer has a plurality of first opens. The second woven dielectric layer is stacked below the first woven dielectric layer. The second woven dielectric layer has a plurality of second opens. The plurality of first opens and the plurality of second opens are misaligned from a top view.

Another aspect of the present disclosure provides a circuit structure configured to decrease a phase difference between a first signal and a second signal. The circuit structure includes a substrate. The substrate includes a power splitter, a first fiberglass layer, and a second fiberglass layer. The power splitter is disposed on a top conductive layer of the substrate, and the power splitter is configured to split a source signal into the first signal and the second signal. The first fiberglass layer is formed in a first configuration, and the first fiberglass layer is disposed below the top conductive layer. The second fiberglass layer is formed in a second configuration, and the second fiberglass layer is disposed below the first woven fiberglass layer. The first configuration is different from the second configuration.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A circuit structure, configured to decrease a phase difference between a first signal and a second signal, comprising:
a substrate, comprising:
a first conductive layer, disposed over the substrate, wherein the first conductive layer comprises a circuit pattern configured to transmit the first signal and the second signal;
a first woven dielectric layer, stacked below the first conductive layer, wherein the first woven dielectric layer has a plurality of first opens; and
a second woven dielectric layer, stacked below the first woven dielectric layer, wherein the second woven dielectric layer has a plurality of second opens,
wherein the plurality of first opens and the plurality of second opens are misaligned from a top view.

2. The circuit structure of claim 1, wherein the first woven dielectric layer comprises:
a plurality of first fiberglass strips, disposed along a first direction; and
a plurality of second fiberglass strips, disposed along a second direction perpendicular to the first direction,
wherein the plurality of first fiberglass strips and the plurality of second fiberglass strips are woven together, and the plurality of first opens are formed between two adjacent first fiberglass strips and two adjacent second fiberglass strips.

3. The circuit structure of claim 2, wherein the second woven dielectric layer comprises:
a plurality of third fiberglass strips, disposed along a third direction; and
a plurality of fourth fiberglass strips, disposed along a fourth direction perpendicular to the fourth direction,
wherein the plurality of third fiberglass strips and the plurality of fourth fiberglass strips are woven together, and the plurality of second opens are formed between two adjacent third fiberglass strips and two adjacent fourth fiberglass strips.

4. The circuit structure of claim 3, wherein an included angle of the first direction and the third direction is ranged from 0 to 90 degree.

5. The circuit structure of claim 3, wherein an included angle of the first direction and the third direction is about 45 degree.

6. The circuit structure of claim 1, wherein the substrate further comprises:
a second conductive layer, stacked below the second woven dielectric layer,
wherein the substrate is a printed circuit board.

7. The circuit structure of claim 1, wherein the circuit pattern is further configured to receive a source signal and split the source signal into the first signal and the second signal, and the circuit pattern comprises:
an input terminal, configured to receive the source signal;
a first output terminal, configured to output the first signal; and
a second output terminal, configured to output the second signal,
wherein the circuit pattern is a power splitter circuit.

8. The circuit structure of claim 7, further comprising:
a chip, disposed on the first conductive layer and coupled to the first output terminal and the second output terminal of the circuit pattern, configured to respectively receive the first signal and the second signal to generate a third signal and a fourth signal;
a phase shifter array, coupled to the chip, configured to adjust a phase of the third signal and a phase of the fourth signal to generate a fifth signal and a sixth signal, respectively; and
an antenna array, coupled to the phase shifter array, configured to transmit the fifth signal and the sixth signal according to a phase of fifth signal and a phase of the sixth signal, respectively.

9. The circuit structure of claim 1, wherein the circuit pattern comprises:
a first conductive trace, configured to transmit the first signal from a first node of the circuit pattern to a second node of the circuit pattern; and
a second conductive trace, configured to transmit the second signal from a third node of the circuit pattern to a fourth node of the circuit pattern,
wherein a phase difference between the first signal at the second node and the first signal at the first node is substantially equal to a phase difference between the second signal at the fourth node and the second signal at the third node.

10. The circuit structure of claim 1, wherein the first signal and the second signal are a differential pair.

11. A circuit structure, configured to decrease a phase difference between a first signal and a second signal, comprising:
a substrate, comprising:
a power splitter, disposed on a top conductive layer of the substrate, configured to split a source signal into the first signal and the second signal;
a first fiberglass layer, formed in a first configuration, disposed below the top conductive layer; and
a second fiberglass layer, formed in a second configuration, disposed below the first woven fiberglass layer,
wherein the first configuration is different from the second configuration.

12. The circuit structure of claim 11, further comprising:
a chip, coupled to the power splitter, configured to receive the first signal and the second signal to generate a third signal and a fourth signal, respectively.

13. The circuit structure of claim 12, further comprising:
a phase shifter array, configured to perform a phase shifting on the third signal and the fourth signal to generate a fifth signal and a sixth signal, respectively; and
an antenna array, configured to transmit the fifth signal and the sixth signal according to a phase of fifth signal and a phase of the sixth signal, respectively.

14. The circuit structure of claim 11, wherein the first fiberglass layer comprises:
a plurality of first fiberglass strips, disposed along a first direction; and
a plurality of second fiberglass strips, disposed along a second direction perpendicular to the first direction,
wherein the plurality of first fiberglass strips and the plurality of second fiberglass strips are woven together, and a plurality of first opens are formed between two adjacent first fiberglass strips and two adjacent second fiberglass strips.

15. The circuit structure of claim 14, wherein the second fiberglass layer comprises:
a plurality of third fiberglass strips, disposed along a third direction; and
a plurality of fourth fiberglass strips, disposed along a fourth direction perpendicular to the fourth direction,
wherein the plurality of third fiberglass strips and the plurality of fourth fiberglass strips are woven together, and a plurality of second opens are formed between two adjacent third fiberglass strips and two adjacent fourth fiberglass strips.

16. The circuit structure of claim 15, wherein an included angle of the first direction and the third direction is greater than 0 degree and less than 90 degree.

17. The circuit structure of claim 11, wherein the substrate further comprises:
a bottom conductive layer, wherein the bottom conductive layer and the top conductive layer sandwich the first fiberglass layer and the second fiberglass layer.

18. The circuit structure of claim 11, wherein the first signal, the second signal, and the source signal are radio frequency signal.

19. The circuit structure of claim 11, wherein the power splitter comprises:
an input terminal, configured to receive the source signal;
a splitting node, wherein the source signal is spitted to the first signal and the second signal at the splitting node;
a first output terminal, configured to output the first signal;
a second output terminal, configured to output the second signal;
a source conductive trace, coupling the input terminal to the splitting node;
a first conductive trace, coupling the splitting node to the first output terminal, configured to transmit the first signal; and
a second conductive trace, coupling the splitting node to the second output terminal, configured to transmit the second signal.

20. The circuit structure of claim 19, wherein a phase difference between the first signal at the splitting node and the first signal at the first output terminal is substantially equal to a phase difference between the second signal at the splitting node and the second signal at the second output terminal.
